(19) United States
(12) Patent Application Publication
(10) Pub. No.: US 2026/0122883 A1
(43) Pub. Date: Apr. 30, 2026

(54) SEMICONDUCTOR STRUCTURE AND MANUFACTURING METHOD THEREFOR

(71) Applicant: CXMT Corporation, Hefei City (CN)

(72) Inventor: CHIH-CHENG LIU, Hefei City (CN)

(21) Appl. No.: 19/432,910

(22) Filed: Dec. 24, 2025

Related U.S. Application Data
(63) Continuation of application No. PCT/CN2023/141232, filed on Dec. 22, 2023.

(30) Foreign Application Priority Data
Dec. 12, 2023 (CN) 202311708789.1

(51) Int. Cl. H10B 12/00; H10D 30/63

(52) U.S. Cl. CPC H10B 12/315; H10B 12/053; H10B 12/34; H10D 30/63

(57) ABSTRACT

Disclosed are a semiconductor structure and a manufacturing method therefor. The semiconductor structure comprises: first doped structures each having a first portion, a second portion, and a third portion sequentially arranged in a first direction; second doped structures and third doped structures arranged at intervals, wherein each second doped structure is in contact with and connected to a corresponding first portion, each third doped structure is in contact with and connected to a corresponding third portion, and two adjacent first doped structures in a second direction are in contact with and connected to a same third doped structures; and gate structures each having a first surface and a second surface which are opposite in the second direction, wherein at least the first surface is in contact with and connected to a corresponding second portion, and the second direction intersects the first direction.

### CROSS-REFERENCE TO RELATED APPLICATIONS

The present disclosure is a continuation of International Patent Application No. PCT/CN2023/141232, filed on Dec. 22, 2023, which claims priority to Chinese Patent Application No. 202311708789.1, filed on Dec. 12, 2023. The disclosures of the above-referenced applications are hereby incorporated by reference in their entirety.

### TECHNICAL FIELD

The dynamic random access memory (dynamic random access memory, DRAM) is a memory component configured for storing programs and various pieces of data information. The DRAM generally includes a capacitor and a transistor connected to the capacitor. The capacitor is configured for storing charges representing the stored programs and various pieces of data information, and the transistor is a switch for controlling the inflow and discharge of charges from the capacitor. When data is written, the word line is set to a high level, the transistor is turned on, and the bit line charges the capacitor; when data is read, the word line is also set to a high level, the transistor is turned on, and the capacitor is discharged, so that the bit line obtains a read signal.

However, with the continuous development of the manufacturing process of the semiconductor structure, the process nodes of the semiconductor structure are continuously reduced, so that the sizes of functional structures in the semiconductor structure are gradually reduced, and the spacing between the functional structures is gradually reduced. For example, the spacing between the capacitor and the bit line located on the same side of the transistor is reduced, which easily increases the coupling effect between the capacitor and the bit line, resulting in a decrease in the electrical performance of the semiconductor structure.

### BACKGROUND

The common type of dynamic random access memory (dynamic random access memory, DRAM) is 1T1C, that is, the source or drain of a transistor is electrically connected to a capacitor to form a memory cell structure. According to the structure, the capacitor is used to store data. However, since charges on the capacitor will be consumed during reading, and the capacitor itself is also subject to leakage, charges in the capacitor need to be continuously refreshed, resulting in higher power consumption and unstable electrical performance in DRAM. At the same time, due to the large area occupied by the manufacturing process of the capacitor, the size reduction is also a problem.

In order to overcome the problems caused by the capacitor, the memory cell structure without a capacitor has been used, but the electrical performance of the memory cell structure without a capacitor needs to be studied.

### SUMMARY

Embodiments of the present disclosure provide a semiconductor structure and a method for manufacturing the same, which are at least conducive to improving the electrical performance of the semiconductor structure.

According to some embodiments of the present disclosure, in one aspect, the embodiments of the present disclosure provide a semiconductor structure. The semiconductor structure includes: a first doped structure, provided with a first portion, a second portion, and a third portion that are sequentially arranged along a first direction; a second doped structure and a third doped structure that are spaced apart, where the second doped structure is in contact with the first portion, and the third doped structure is in contact with the third portion, where the first doped structure is doped with one of N-type doping ions and P-type doping ions, the second doped structure and the third doped structure are doped with the other of the N-type doping ions and the P-type doping ions, two adjacent first doped structures along a second direction are in contact with a same third doped structure, and the second direction intersects with the first direction; and a gate structure, provided with a first surface and a second surface that are opposite to each other along the second direction, at least the first surface or the second surface being in contact with the second portion.

In some embodiments, in the gate structure, the first surface or the second surface is in contact with the second portion.

In some embodiments, the gate structure is provided with a third surface and a fourth surface that are opposite to each other along the first direction, at least a part of the third surface is also in contact with the second portion, and at least a part of the fourth surface is also in contact with the second portion.

In some embodiments, the gate structure is provided with a third surface and a fourth surface that are opposite to each other along the first direction, and the second surface and the fourth surface are also in contact with the second portion.

In some embodiments, the semiconductor structure further includes an isolation layer in contact with the third surface, and the isolation layer and the gate structure are both embedded into the first doped structure.

In some embodiments, the semiconductor structure further includes an active region. The active region includes two adjacent first doped structures along the second direction, and two gate structures in contact with the two first doped structures are spaced apart from each other and both located in the active region.

In some embodiments, at least a part of the second doped structure is embedded into the first portion, and/or at least a part of the third doped structure is embedded into the third portion.

In some embodiments, a plurality of first doped structures and a plurality of second doped structures are spaced apart along a third direction. The plurality of first doped structures and the plurality of second doped structures that are spaced apart along the third direction are all in a one-to-one correspondence with the gate structures. The third doped structure extends along the third direction, one third doped structure is in contact with the plurality of first doped structures spaced apart along the third direction, and every two of the first direction, the second direction, and the third direction intersect with each other.

In some embodiments, a plurality of first doped structures, a plurality of second doped structures, and a plurality of third doped structures are spaced apart along a third direction. The plurality of first doped structures, the plurality of second doped structures, and the plurality of third doped structures that are spaced apart along the third direction are all in a one-to-one correspondence with the gate structures. The semiconductor structure further includes a conductive layer extending along the third direction, and a same conductive layer is in contact with the plurality of third doped structures spaced apart along the third direction.

In some embodiments, the semiconductor structure further includes a first electrical connection layer. The first electrical connection layer is located on one side of the third doped structure distal to the gate structure, and the first electrical connection layer extends along a third direction.

In some embodiments, the gate structure is in contact with the third doped structure.

In some embodiments, the gate structure includes a gate dielectric layer and a gate, and the gate dielectric layer is located between the gate and the second portion.

In some embodiments, the gate and the third doped structure are spaced apart by at least the gate dielectric layer.

In some embodiments, at least a partial region of the second doped structure is in contact with the gate dielectric layer.

In some embodiments, the semiconductor structure further includes a base substrate, and the first doped structure, the second doped structure, the third doped structure, and the gate structure are all located in the base substrate.

According to some embodiments of the present disclosure, in another aspect, the embodiments of the present disclosure further provide a method for manufacturing a semiconductor structure. The method for manufacturing a semiconductor structure includes: providing an initial base substrate; performing doping treatment on different parts of the initial base substrate by different doping processes to form a first doped structure, a second doped structure, and a third doped structure, where the first doped structure is provided with a first portion, a second portion, and a third portion that are sequentially arranged along a first direction; the second doped structure and the third doped structure are spaced apart, the second doped structure is in contact with the first portion, and the third doped structure is in contact with the third portion; the first doped structure is doped with one of N-type doping ions and P-type doping ions, and the second doped structure and the third doped structure are doped with the other of the N-type doping ions and the P-type doping ions; two adjacent first doped structures along a second direction are in contact with a same third doped structure, and the second direction intersects with the first direction; and forming a gate structure, where the gate structure is provided with a first surface and a second surface that are opposite to each other along the second direction, at least the first surface is in contact with the second portion, and the gate structure is in contact with the third doped structure.

In some embodiments, the initial base substrate is provided with a front surface and a back surface that are opposite to each other along the first direction; the step of forming the second doped structure and the third doped structure includes: performing first doping treatment on a partial region of the initial base substrate to form a plurality of initial first doped structures spaced apart, where each of the plurality of initial first doped structures extends from the front surface toward inside of the initial base substrate, the initial first doped structure also extends along a fourth direction, and the initial first doped structure is provided with a fourth portion, a fifth portion, and a sixth portion that are sequentially arranged along the fourth direction; performing second doping treatment on both the fourth portion and the sixth portion, so that along the first direction, the fourth portion of a partial thickness is converted into one second doped structure, and the sixth portion of a partial thickness is converted into another second doped structures, each of the second doped structures extending from the front surface toward the inside of the initial base substrate; patterning the initial base substrate from the back surface to expose at least a part of the fifth portion; and performing third doping treatment on the exposed fifth portion to form the third doped structure.

In some embodiments, a plurality of fifth portions are spaced apart along a third direction, and every two of the first direction, the second direction, and the third direction intersect with each other; patterning the initial base substrate from the back surface includes: patterning the initial base substrate from the back surface to form a trench extending along the third direction, where the trench exposes the plurality of fifth portions spaced apart along the third direction; performing the third doping treatment on the exposed fifth portion includes: performing the third doping treatment on the fifth portion exposed by the trench to form the third doped structure extending along the third direction; the method for manufacturing a semiconductor structure further includes: forming a first electrical connection layer, where the first electrical connection layer fills up the trench.

In some embodiments, a plurality of fifth portions are spaced apart along a third direction, and every two of the first direction, the second direction, and the third direction intersect with each other; patterning the initial base substrate from the back surface includes: patterning the initial base substrate from the back surface to form a plurality of through holes spaced apart along the third direction, where each of the plurality of through holes exposes one of the plurality of fifth portions; performing the third doping treatment on the exposed fifth portion includes: performing the third doping treatment on the fifth portion exposed by the through hole to form a plurality of third doped structures spaced apart along the third direction; the method for manufacturing a semiconductor structure further includes: forming conductive pillars, where the conductive pillars fill up the plurality of through holes, and the conductive pillars are in a one-to-one correspondence with the plurality of through holes; and forming a second electrical connection layer extending along the third direction, where a same second electrical connection layer is in contact with a plurality of conductive pillars spaced apart along the third direction.

In some embodiments, after forming the second doped structure, the method for manufacturing a semiconductor structure further includes: forming, on the front surface, a capacitor structure in contact with the second doped structure, and one second doped structure corresponds to one capacitor structure.

The technical solutions according to the embodiments of the present disclosure at least have the following advantages:

The first portion and the third portion are spaced apart along the first direction, the second doped structure and the third doped structure are spaced apart, the second doped structure is in contact with the first portion, the third doped structure is in contact with the third portion, the second portion is located between the first portion and the third portion, and the gate structure is in contact with the second portion. In this way, the second doped structure and the third doped structure may be regarded as being located on two opposite sides of the gate structure along the first direction. That is, taking a plane parallel to the first direction as a reference plane, the second doped structure and the third doped structure are not directly opposite to each other; that is, the orthographic projections of the second doped structure and the third doped structure on the reference plane do not overlap, so as to increase the spacing between the second doped structure and the third doped structure, thereby helping to reduce the coupling effect of the second doped structure and the third doped structure on each other. Further, after a first conductive structure is formed on one side of one of the second doped structure and the third doped structure distal to the gate structure, and a second conductive structure is formed on one side of the other of the second doped structure and the third doped structure distal to the gate structure, it is conducive to preventing the first conductive structure and the second conductive structure from being directly opposite to each other, thereby helping to reduce the coupling effect of the first conductive structure and the second conductive structure on each other and thus improving the electrical performance of the semiconductor structure.

Moreover, it can be understood that the first doped structure, the second doped structure, the third doped structure, and the gate structure jointly constitute a transistor structure. The second doped structure and the third doped structure are not in direct contact, but the second doped structure and the third doped structure are separately in contact with the first doped structure; that is, one of the second doped structure and the third doped structure may serve as the source of the transistor structure, and the other may serve as the drain of the transistor structure. A part of the first doped structure may serve as the channel region of the transistor structure, and the gate structure controls the turn-on or turn-off of the channel region. Two adjacent first doped structures along the second direction are in contact with the same third doped structure, that is, two adjacent transistor structures along the second direction share one third doped structure, which is conducive to improving the integration density of the transistor structures in the semiconductor structure.

### BRIEF DESCRIPTION OF DRAWINGS

One or more embodiments are illustrated by figures in the corresponding drawings. These exemplary explanations do not constitute limitations on the embodiments, and elements with identical reference numerals in the drawings represent similar elements. Unless expressly stated otherwise, the figures in the drawings do not constitute a proportion limitation. To more clearly illustrate the technical solutions in the embodiments of the present disclosure or prior art, a brief introduction to the drawings required for the description of the embodiments is given hereinafter. It is evident that the drawings described hereinafter are merely some embodiments of the present disclosure. For those of ordinary skill in the art, other drawings may also be obtained based on these drawings without creative effort.

FIGS. 1 to 4 are schematic diagrams of four partial cross-sectional structures of a semiconductor structure according to an embodiment of the present disclosure;

FIG. 5 is a schematic top view of a semiconductor structure according to an embodiment of the present disclosure;

FIGS. 6 and 7 are schematic diagrams of another two partial cross-sectional structures of a semiconductor structure according to an embodiment of the present disclosure;

FIGS. 8 and 9 are another two schematic top views of a semiconductor structure according to an embodiment of the present disclosure;

FIG. 10 is a schematic diagram of yet another partial cross-sectional structure of a semiconductor structure according to an embodiment of the present disclosure; and

FIGS. 11 to 19 are schematic diagrams of cross-sectional structures corresponding to steps in a method for manufacturing a semiconductor structure according to another embodiment of the present disclosure.

### DESCRIPTION OF EMBODIMENTS

It can be known from the background that the electrical performance of the semiconductor structure needs to be improved.

Embodiments of the present disclosure provide a semiconductor structure and a method for manufacturing the same. According to the semiconductor structure, a second doped structure and a third doped structure may be regarded as being located on two opposite sides of a gate structure along a first direction X. That is, taking a plane parallel to the first direction X as a reference plane, the second doped structure and the third doped structure are not directly opposite to each other; that is, the orthographic projections of the second doped structure and the third doped structure on the reference plane do not overlap, so as to increase the spacing between the second doped structure and the third doped structure, thereby helping to reduce the coupling effect of the second doped structure and the third doped structure on each other. Further, when conductive structures are formed on one side of the second doped structure and the third doped structure distal to the gate structure, respectively, it is conducive to preventing the two conductive structures from being directly opposite to each other, thereby helping to reduce the coupling effect of the two conductive structures on each other and thus improving the electrical performance of the semiconductor structure. Moreover, a first doped structure, the second doped structure, the third doped structure, and the gate structure jointly constitute a transistor structure, and two adjacent first doped structures along a second direction are in contact with the same third doped structure, that is, two adjacent transistor structures along the second direction share one third doped structure, which is conducive to improving the integration density of the transistor structures in the semiconductor structure.

The embodiments of the present disclosure will be described in detail below with reference to the drawings. However, those of ordinary skill in the art can understand that in the embodiments of the present disclosure, numerous technical details are set forth in order to enable readers to better understand the embodiments of the present disclosure. However, the technical solutions claimed by the embodiments of the present disclosure can also be implemented even without these technical details and the various changes and modifications based on the following embodiments.

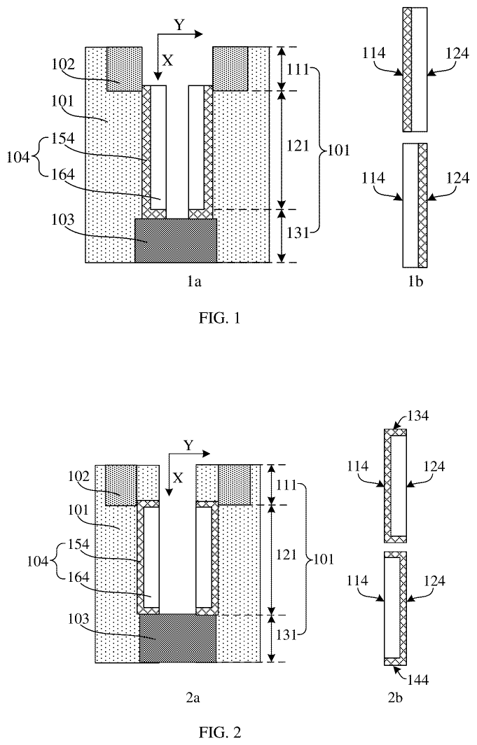

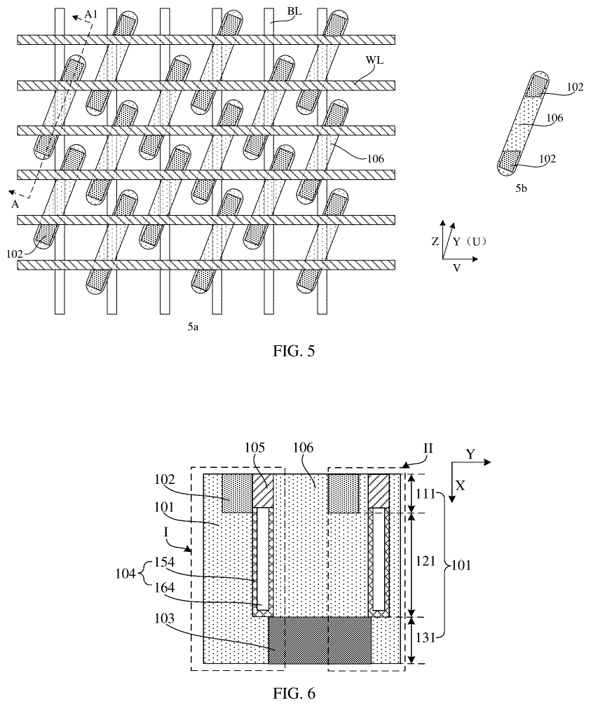

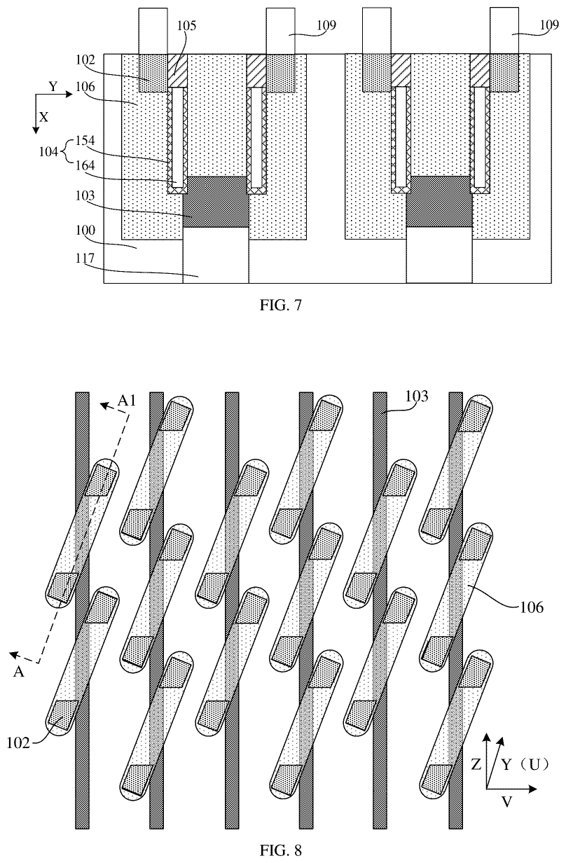

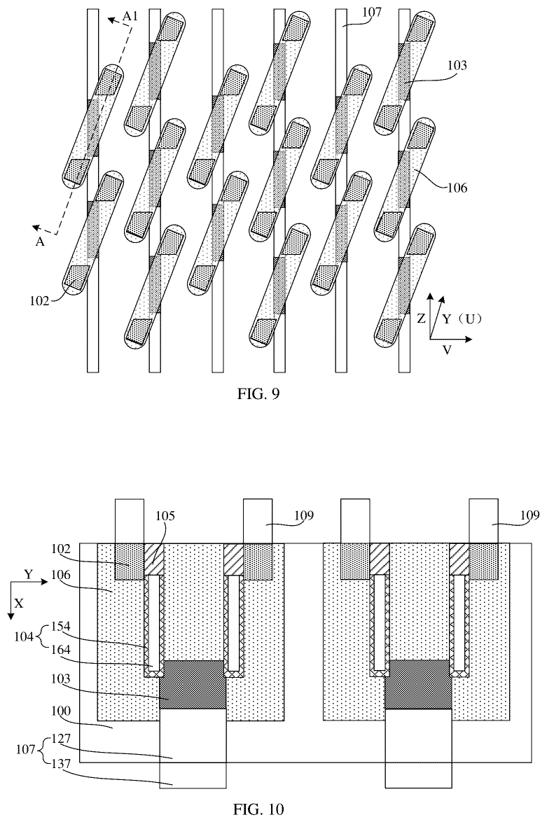

An embodiment of the present disclosure provides a semiconductor structure. The semiconductor structure according to this embodiment of the present disclosure is described in detail below with reference to the drawings. FIGS. 1 to 4 are schematic diagrams of four partial cross-sectional structures of a semiconductor structure according to an embodiment of the present disclosure; FIG. 5 is a schematic top view of a semiconductor structure according to an embodiment of the present disclosure; FIGS. 6 and 7 are schematic diagrams of another two partial cross-sectional structures of a semiconductor structure according to an embodiment of the present disclosure; FIGS. 8 and 9 are another two schematic top views of a semiconductor structure according to an embodiment of the present disclosure; FIG. 10 is a schematic diagram of yet another partial cross-sectional structure of a semiconductor structure according to an embodiment of the present disclosure. It should be noted that, for convenience of description and clear illustration of the semiconductor structure, FIGS. 1 to 10 in the embodiment of the present disclosure are all schematic diagrams showing a partial structure of the semiconductor structure.

Referring to FIGS. 1 to 4, the semiconductor structure may include: a first doped structure 101, provided with a first portion 111, a second portion 121, and a third portion 131 that are sequentially arranged along a first direction X; a second doped structure 102 and a third doped structure 103 that are spaced apart, where the second doped structure 102 is in contact with the first portion 111, and the third doped structure 103 is in contact with the third portion 131, where the first doped structure 101 is doped with one of N-type doping ions and P-type doping ions, the second doped structure 102 and the third doped structure 103 are doped with the other of the N-type doping ions and the P-type doping ions, two adjacent first doped structures 101 along a second direction Y are in contact with the same third doped structure 103, and the second direction Y intersects with the first direction X; and a gate structure 104, provided with a first surface 114 and a second surface 124 that are opposite to each other along the second direction Y, where at least the first surface 114 or the second surface 124 is in contact with the second portion 121.

In some embodiments, the first doped structure 101 may be doped with the P-type doping ions, and the second doped structure 102 and the third doped structure 103 may be doped with the N-type doping ions. In some other embodiments, the first doped structure 101 may be doped with the N-type doping ions, and the second doped structure 102 and the third doped structure 103 may be doped with the P-type doping ions.

It should be noted that, for convenience of description, the following description is given by taking the case where the first doped structure 101 may be doped with the P-type doping ions, and the second doped structure 102 and the third doped structure 103 may be doped with the N-type doping ions as an example.

In some embodiments, the N-type doping ions include at least one of an arsenic ion, a phosphorus ion, or an antimony ion; the P-type doping ions include at least one of a boron ion, an indium ion, or a gallium ion.

It can be understood that the first doped structure 101, the second doped structure 102, the third doped structure 103, and the gate structure 104 jointly constitute a transistor structure. The second doped structure 102 and the third doped structure 103 are not in direct contact, but the second doped structure 102 and the third doped structure 103 are separately in contact with the first doped structure 101; that is, one of the second doped structure 102 and the third doped structure 103 may serve as the source of the transistor structure, and the other may serve as the drain of the transistor structure. A part of the first doped structure 101 may serve as the channel region of the transistor structure, and the gate structure 104 controls the turn-on or turn-off of the channel region. It should be noted that, for convenience of description, the following description is given by taking the case where the second doped structure 102 is the drain of the transistor structure and the third doped structure 103 is the source of the transistor structure as an example.

In this way, two adjacent first doped structures 101 along the second direction Y are in contact with the same third doped structure 103, that is, two adjacent transistor structures along the second direction Y share one third doped structure 103, which is conducive to improving the integration density of the transistor structures in the semiconductor structure.

It should be noted that, in the gate structure 104, at least the first surface 114 is in contact with the second portion 121. The relative position relationship between the gate structure 104 and the second portion 121 will be described in detail later.

It can be understood that the first portion 111 and the third portion 131 are spaced apart along the first direction X, the second doped structure 102 and the third doped structure 103 are spaced apart, the second doped structure 102 is in contact with the first portion 111, the third doped structure 103 is in contact with the third portion 131, the second portion 121 is located between the first portion 111 and the third portion 131, and the gate structure 104 is in contact with the second portion 121. In this way, the second doped structure 102 and the third doped structure 103 may be regarded as being located on two opposite sides of the gate structure 104 along the first direction X. That is, taking a plane parallel to the first direction X as a reference plane, the second doped structure 102 and the third doped structure 103 are not directly opposite to each other; that is, the orthographic projections of the second doped structure 102 and the third doped structure 103 on the reference plane do not overlap, so as to increase the spacing between the second doped structure 102 and the third doped structure 103, thereby helping to reduce the coupling effect of the second doped structure 102 and the third doped structure 103 on each other. Further, after a first conductive structure is formed on one side of one of the second doped structure 102 and the third doped structure 103 distal to the gate structure 104, and a second conductive structure is formed on one side of the other of the second doped structure and the third doped structure distal to the gate structure 104, it is conducive to preventing the first conductive structure and the second conductive structure from being directly opposite to each other, thereby helping to reduce the coupling effect of the first conductive structure and the second conductive structure on each other and thus improving the electrical performance of the semiconductor structure.

In some embodiments, the first conductive structure may be a capacitor structure, and the second conductive structure may be a bit line structure. The bit line structure and the capacitor structure will be described in detail later.

One embodiment of the present disclosure is described in more detail below with reference to the drawings.

In some embodiments, referring to FIGS. 1 to 4, the gate structure 104 may include a gate dielectric layer 154 and a gate 164. The gate dielectric layer 154 is located between the gate 164 and the second portion 121. It may be understood that, regardless of the position relationship between the gate 164 and the second portion 121, the gate 164 and the second portion 121 are spaced apart by the gate dielectric layer 154.

In some embodiments, the gate dielectric layer 154 may be made of a material with a high relative dielectric constant, such as silicon oxide, hafnium oxide, or zirconium oxide.

In some embodiments, the gate 164 may be made of a metal material, such as titanium, tungsten, or copper, or the gate 164 may be made of a compound such as titanium nitride.

The position relationship between the gate structure 104 and the second portion 121 includes at least the following embodiments.

In some embodiments, referring to FIG. 1, in the gate structure 104, the first surface 114 is in contact with the second portion 121. In some other embodiments, still referring to FIG. 1, in the gate structure 104, the second surface 124 is in contact with the second portion 121. It may be understood that, along the second direction Y, in the gate structure 104, one surface is in contact with the second portion 121; that is, the gate dielectric layer 154 is located on the surface of the second portion 121 and is not embedded into the second portion 121, the gate 164 is located on one side of the gate dielectric layer 154 distal to the second portion 121, and the gate dielectric layer 154 is also at least located between the third doped structure 103 and the gate 164.

It should be noted that 1a in FIG. 1 is a schematic diagram of a partial cross-sectional structure of a semiconductor structure according to an embodiment of the present disclosure, and 1b in FIG. 1 is a schematic diagram of cross-sectional structures of the two gate structures 104 shown in 1a. It may be understood that, based on the change in the relative position relationship between the gate structure 104 and the second portion 121, the gate dielectric layer 154 in the gate structure 104 may form the first surface 114, or may form the second surface 124.

In some embodiments, still referring to FIG. 1, on the basis that two adjacent first doped structures 101 along the second direction Y are in contact with the same third doped structure 103, two gate structures 104 corresponding to two adjacent second portions 121 along the second direction Y may be both located between the two second portions 121, and the two gate structures 104 are spaced apart from each other. For example, the two adjacent first doped structures 101 along the second direction Y are marked as A and B, the gate structure 104 in contact with A is regarded as C, and the gate structure 104 in contact with B is regarded as D. Along the second direction Y, C is located on one side of A proximal to B, and D is located on one side of B proximal to A; that is, the first surface 114 of C is in contact with the second portion 121, and the second surface 124 of D is in contact with the second portion 121.

In practical applications, along the second direction Y, on the basis that C is located on one side of A proximal to B, D may alternatively be located on one side of B distal to A, and there is one C between A and B. In other words, in both C and D, the first surface 114 is in contact with the second portion 121.

In some other embodiments, referring to FIG. 2, on the basis that in the gate structure 104, the first surface 114 or the second surface 124 is in contact with the second portion 121, the gate structure 104 is provided with a third surface 134 and a fourth surface 144 that are opposite to each other along the first direction X, at least a part of the third surface 134 is also in contact with the second portion 121, and at least a part of the fourth surface 144 is also in contact with the second portion 121. It can be understood that the gate dielectric layer 154 forms a first groove with an opening facing the second direction Y, the outer wall of the first groove is in contact with the second portion 121, the inner wall of the first groove is in contact with the gate 164, and the gate 164 fills up the first groove.

It should be noted that, 2a in FIG. 2 shows an example in which both the entire third surface 134 and the entire fourth surface 144 are in contact with the second portion 121, that is, the gate structure 104 is entirely embedded into the second portion 121, and the first surface 114 or the second surface 124 is exposed from the second portion 121. In practical applications, alternatively, a part of the third surface 134 may be in contact with the second portion 121, and a part of the fourth surface 144 may be in contact with the second portion 121, that is, a part of the gate structure 104 is embedded into the second portion 121. In addition, 2a in FIG. 2 is a schematic diagram of another partial cross-sectional structure of a semiconductor structure according to an embodiment of the present disclosure, and 2b in FIG. 2 is a schematic diagram of cross-sectional structures of the two gate structures 104 shown in 2a.

In some embodiments, still referring to FIG. 2, on the basis that two adjacent first doped structures 101 along the second direction Y are in contact with the same third doped structure 103, two gate structures 104 corresponding to two adjacent second portions 121 along the second direction Y may be both located between the two second portions 121, and the two gate structures 104 are spaced apart from each other. For example, the two adjacent first doped structures 101 along the second direction Y are marked as A and B, the gate structure 104 in contact with A is regarded as C, and the gate structure 104 in contact with B is regarded as D. Along the second direction Y, C is located on one side of A proximal to B, and D is located on one side of B proximal to A; that is, the first surface 114, at least a part of the third surface 134, and at least a part of the fourth surface 144 of C are all in contact with the second portion 121, and the second surface 124, at least a part of the third surface 134, and at least a part of the fourth surface 144 of D are all in contact with the second portion 121.

In practical applications, along the second direction Y, on the basis that C is located on one side of A proximal to B, D may alternatively be located on one side of B distal to A, and there is one C between A and B. In other words, in both C and D, the first surface 114, at least a part of the third surface 134, and at least a part of the fourth surface 144 are in contact with the second portion 121.

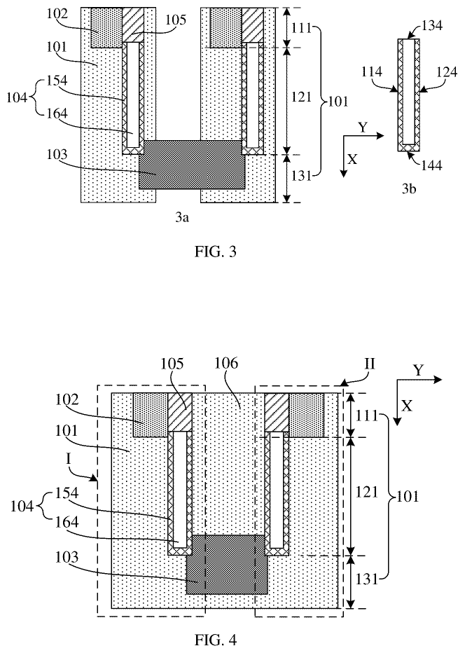

In yet other embodiments, referring to FIGS. 3 and 4, on the basis that in the gate structure 104, the first surface 114 or the second surface 124 is in contact with the second portion 121, the gate structure 104 is provided with a third surface 134 and a fourth surface 144 that are opposite to each other along the first direction X, and the second surface 124 and the fourth surface 144 are also in contact with the second portion 121, that is, the entire gate structure 104 is embedded into the second portion 121. It can be understood that the gate dielectric layer 154 forms a second groove with an opening facing the first direction X, the outer wall of the second groove is in contact with the second portion 121, the inner wall of the second groove is in contact with the gate 164, and the gate 164 fills up the second groove.

It should be noted that 3a in FIG. 3 is a schematic diagram of yet another partial cross-sectional structure of a semiconductor structure according to an embodiment of the present disclosure, and 3b in FIG. 3 is a schematic diagram of a cross-sectional structure of any one of the gate structures 104 shown in 3a.

In some embodiments, still referring to FIGS. 3 and 4, the semiconductor structure may further include an isolation layer 105 in contact with the third surface 134, and the isolation layer 105 and the gate structure 104 are both embedded into the first doped structure 101.

In some embodiments, the isolation layer 105 may be made of a dielectric material such as silicon nitride, silicon oxynitride, or silicon carbonitride.

In some embodiments, referring to FIG. 4, the semiconductor structure may further include an active region 106. The active region 106 includes two adjacent first doped structures 101 along the second direction Y, and two gate structures 104 in contact with the two first doped structures 101 are spaced apart from each other and both located in the active region 106.

It should be noted that, in FIG. 4, the regions of the two first doped structures 101 in the active region 106 are roughly outlined by box I and box II, respectively. In practical applications, the active region 106 is of an integral structure. For convenience of description of the position relationship between different second doped structures 102, different gate structures 104, and third doped structures 103 in the active region 106, the active region 106 is divided to obtain two first doped structures 101.

It can be understood that the active region 106 including the two adjacent first doped structures 101 along the second direction Y means that the two adjacent first doped structures 101 along the second direction Y are both a part of the active region 106. Referring to FIGS. 4 and 5, one active region 106 corresponds to two second doped structures 102, two gate structures 104, and one third doped structure 103. One second doped structure 102, one gate structure 104, and the third doped structure 103 constitute one transistor structure; the other second doped structure 102, the other gate structure 104, and the third doped structure 103 constitute another transistor structure. That is, one active region 106 corresponds to two transistor structures.

It should be noted that 5a in FIG. 5 is a schematic top view of a relative position relationship between the active region 106, and the bit line structure BL and the word line structure WL in the semiconductor structure; 5b in FIG. 5 is a schematic top view of any active region 106 shown in 5a and its two corresponding second doped structures 102; FIG. 4 is a schematic diagram of a partial cross-sectional structure of the semiconductor structure shown in 5a in FIG. 5 along a first cross-sectional direction AA1, where the first cross-sectional direction AA1 is the second direction Y, that is, the extension direction U of the active region 106. It can be understood that the bit line structure BL and the word line structure WL shown in FIG. 5 are merely used to illustrate the relative position relationship of the bit line structure BL, the word line structure WL, and the active region 106 in the top view. FIG. 5 does not limit the internal structure of the bit line structure BL and the word line structure WL themselves, and does not limit the three-dimensional position relationship of the bit line structure BL, the word line structure WL, and the active region 106. In addition, in order to clearly illustrate the relative position relationship of the active region 106, the bit line structure BL, and the word line structure WL in the top view, the word line structure WL and the active region 106 are drawn in a perspective manner. Moreover, for convenience of illustration, the third doped structure 103 and the gate structure 104 that are embedded into the active region 106 are not shown in FIG. 5.

In some embodiments, a shallow trench isolation structure (not shown) is provided between adjacent active regions 106.

In some embodiments, the extension direction of the bit line structure BL is a third direction Z, and the extension direction of the word line structure WL is a fifth direction V. Referring to 5a in FIG. 5, a plurality of active regions 106 are spaced apart along the third direction Z and the fifth direction V; moreover, two adjacent active region groups spaced apart along the fifth direction V are offset in the third direction Z. Every two of the extension direction U of the active region 106 itself, the first direction X, and the second direction Y intersect with each other; moreover, the extension direction U of the active region 106 itself, the third direction Z, and the fifth direction V are located in one plane. It can be understood that, when a plurality of active regions 106 spaced apart along the third direction Z are regarded as one column, two adjacent columns are offset along the fifth direction V, and two columns spaced apart by one column are arranged in the same manner.

It should be noted that, in practical applications, the plurality of active regions may also be arranged in an array or in other arrangement manners along the third direction Z and the fifth direction V, and the arrangement manner of the plurality of active regions may be adjusted according to actual needs and is not limited herein. For convenience of description, the following detailed description is given by taking the case where the plurality of active regions 106 are arranged in the arrangement manner shown in 5a in FIG. 5 as an example.

In some embodiments, referring to FIGS. 4 and 5, the word line structure WL includes a plurality of gate structures 104 spaced apart along the third direction Z and isolation layers 105 located on the gate structures 104. In some other embodiments, the plurality of gate structures 104 spaced apart along the third direction Z may be an integrated structure extending along the third direction Z, that is, the plurality of active regions 106 spaced apart along the third direction Z share one gate structure 104. On this basis, the isolation layers 105 are also an integrated structure extending along the third direction Z.

In some embodiments, referring to FIGS. 1 to 4, at least a part of the second doped structure 102 is embedded into the first portion 111. It should be noted that FIGS. 1 to 4 all take the case where the second doped structure 102 of the entire thickness along the first direction X is embedded into the first portion 111 as an example. In practical applications, alternatively, the second doped structure 102 of a partial thickness along the first direction X may be embedded into the first portion 111.

In some embodiments, referring to FIGS. 1 to 4, at least a part of the third doped structure 103 is embedded into the third portion 131. It should be noted that FIGS. 1 to 4 all take the case where the third doped structure 103 of the entire thickness along the first direction X is embedded into the third portion 131 as an example. In practical applications, alternatively, the third doped structure 103 of a partial thickness along the first direction X may be embedded into the third portion 131.

It should be noted that the division of the first portion 111, the second portion 121, and the third portion 131 in the first doped structure 101 is related to the relative positions of the second doped structure 102, the gate structure 104, and the third doped structure 103 to the first doped structure 101. In the first doped structure 101, a part that is at least in contact with the second doped structure 102 is regarded as the first portion 111, a part that is at least in contact with the third doped structure 103 is regarded as the third portion 131, and the remaining first doped structure 101 is regarded as the second portion 121.

In some embodiments, referring to FIGS. 2 to 4, the gate structure 104 may be in contact with the third doped structure 103.

In some embodiments, the gate structure 104 may include a gate dielectric layer 154 and a gate 164. The third doped structure 103 is in contact with the gate dielectric layer 154, that is, the gate 164 and the third doped structure 103 are spaced apart by at least the gate dielectric layer 154.

In some embodiments, still referring to FIGS. 2 to 4, on the basis that the gate 164 and the second doped structure 102 are insulated from each other and the gate 164 and the third doped structure 103 are insulated from each other, the third doped structure 103 may be in contact with not only the third portion 131, but also the second portion 121 of a partial thickness along the first direction X.

In some other embodiments, referring to FIG. 6, the second doped structures 102 are in a one-to-one correspondence with the gate structures 104, and the second doped structures 102 are located on the same side of corresponding gate structures 104 along the second direction Y. For example, in FIG. 6, the second doped structures 102 are located on a first side of corresponding gate structures 104, and two adjacent gate structures 104 with an interval therebetween are located in the same active region 106.

It should be noted that, referring to FIGS. 2 to 4 and 6, the gate structure 104 may be in contact with the second portion 121; moreover, on the basis that the gate 164 and the second doped structure 102 are insulated from each other and the gate 164 and the third doped structure 103 are insulated from each other, the gate structure 104 may also be in contact with the first portion 111 of a partial thickness along the first direction X. In practical applications, the gate structure 104 may be in contact with the second portion 121. In addition, in FIG. 6, the regions of the two first doped structures 101 in the active region 106 are roughly outlined by box I and box II, respectively.

In some embodiments, referring to FIG. 7, the semiconductor structure may further include a base substrate 100. The first doped structure 101, the second doped structure 102, the third doped structure 103, and the gate structure 104 are all located in the base substrate 100. It can be understood that a plurality of active regions 106 spaced apart are provided in the base substrate 100, and the first doped structure 101, the second doped structure 102, the third doped structure 103, and the gate structure 104 all have at least a partial region embedded into the active regions 106.

It can be understood that, still referring to FIG. 7, in the same active region 106, along the second direction Y, the third doped structure 103 is located between two adjacent gate structures 104, and the two adjacent gate structures 104 are located between two adjacent second doped structures 102, so that two transistor structures share one third doped structure 103.

The third doped structure 103 is described in detail below in conjunction with two embodiments.

In some embodiments, referring to FIGS. 5 and 7, a plurality of first doped structures 101 and a plurality of second doped structures 102 are spaced apart along the third direction Z; the first doped structures 101 and the second doped structures 102 that are spaced apart along the third direction Z are all in a one-to-one correspondence with the gate structures 104. The third doped structure 103 extends along the third direction Z, and one third doped structure 103 is in contact with the plurality of first doped structures 101 spaced apart along the third direction Z. Every two of the first direction X, the second direction Y, and the third direction Z intersect with each other.

It can be understood that the first doped structure 101 is a part of the active region 106. Two ends of one active region 106 along the extension direction U thereof are separately embedded with one second doped structure 102. A region in the active region 106 that is located between two second doped structures 102 in contact with the active region corresponds to one bit line structure BL and two word line structures WL. For any active region 106, a region corresponding to the word line structure WL is embedded with a gate structure 104, and a region corresponding to the bit line structure BL is embedded with a third doped structure 103. The relationship between the word line structure WL and the gate structure 104, and the relationship between the bit line structure BL and the third doped structure 103 will be described in detail later.

In some embodiments, referring to 5a in FIG. 5, a plurality of bit line structures BL are spaced apart along the fifth direction V, and a plurality of word line structures WL are spaced apart along the third direction Z. It can be understood that the plurality of bit line structures BL and the plurality of word line structures WL form a plurality of rectangular windows in the top view, a capacitor contact hole is formed in each rectangular window, each capacitor contact hole exposes one second doped structure 102, and a capacitor structure in contact with the second doped structure 102 is formed based on the capacitor contact hole.

In some embodiments, referring to 5a in FIG. 5, the active region 106 directly opposite to the word line structure WL is embedded with a gate structure 104 and an isolation layer 105. It can be understood that the word line structure WL includes the gate structure 104 and the isolation layer 105, and a plurality of active regions 106 spaced apart along the fifth direction V are all directly opposite to a partial region of the word line structure WL, that is, the orthographic projection of a part of the gate structure 104 on the active region 106 coincides with the active region 106, and the plurality of active regions 106 spaced apart along the fifth direction V share one gate structure 104.

Referring to FIGS. 7 and 8, the third doped structure 103 extends along the third direction Z. It can be understood that the plurality of active regions 106 spaced apart along the third direction Z are all directly opposite to a partial region of the third doped structure 103, that is, the orthographic projection of a part of the third doped structure 103 on the active region 106 coincides with the active region 106, and the plurality of active regions 106 spaced apart along the third direction Z share one third doped structure 103. It should be noted that the bit line structure BL includes the third doped structure 103. In addition, the first doped structure 101 is a part of the active region 106. Two ends of one active region 106 along the extension direction U thereof are separately embedded with one second doped structure 102. One active region 106 may be regarded as a basic component constituting two transistor structures, and the two transistor structures share one third doped structure 103.

In some embodiments, referring to FIG. 7, the semiconductor structure may further include a first electrical connection layer 117. The first electrical connection layer 117 is located on one side of the third doped structure 103 distal to the gate structure 104, and the first electrical connection layer 117 extends along the third direction Z. It can be understood that the bit line structure BL (referring to FIG. 5) may include a first electrical connection layer 117 and a third doped structure 103 in contact with the first electrical connection layer 117, and one bit line structure BL corresponds to one first electrical connection layer 117 and one third doped structure 103.

It should be noted that, in order to clearly illustrate the relative position relationship between the active region 106 and the third doped structure 103 in the top view, the active region 106 is drawn in a perspective manner in FIG. 8.

In some other embodiments, referring to FIGS. 9 and 10, a plurality of first doped structures 101, a plurality of second doped structures 102, and a plurality of third doped structures 103 are spaced apart along the third direction Z; the first doped structures 101, the second doped structures 102, and the third doped structures 103 that are spaced apart along the third direction Z are all in a one-to-one correspondence with the gate structures 104.

It can be understood that the first doped structure 101 is a part of the active region 106. Two ends of one active region 106 along the extension direction U thereof are separately embedded with one second doped structure 102. In the top view shown in FIG. 9, there is a gate structure 104 (referring to FIG. 7) between the second doped structure 102 and the third doped structure 103 (referring to FIG. 7) corresponding to the same active region 106. It can be understood that the third doped structure 103 may serve as a bit line contact layer in the bit line structure BL. It should be noted that the content that is the same as or corresponding to that in the foregoing embodiments will not be described herein again.

Still referring to FIGS. 9 and 10, the semiconductor structure may further include a conductive layer 107 extending along the third direction Z, and the same conductive layer 107 is in contact with the plurality of third doped structures 103 spaced apart along the third direction Z. It can be understood that one bit line structure BL includes a plurality of third doped structures 103 spaced apart along the third direction Z and one conductive layer 107 in contact with the third doped structures. In addition, one active region 106 may be regarded as a basic component constituting two transistor structures; the two transistor structures include respective second doped structures 102 and respective gate structures 104, and the two transistor structures share one third doped structure 103.

In some embodiments, referring to FIG. 10, the conductive layer 107 may include: a second electrical connection layer 137, and a plurality of conductive pillars 127 that are in contact with the second electrical connection layer 137 and spaced apart along the third direction Z. The conductive pillars 127 are in a one-to-one correspondence with the third doped structures 103, one conductive pillar 127 is in contact with one third doped structure 103, the second electrical connection layer 137 extends along the third direction Z, and the same second electrical connection layer 137 is in contact with the plurality of conductive pillars 127 spaced apart along the third direction Z.

In some embodiments, the orthographic projections of the conductive pillar 127 and the third doped structure 103 on the base substrate 100 may coincide with each other.

It should be noted that, in order to clearly illustrate the relative position relationship between the active region 106 and the third doped structure 103 in the top view, the active region 106 is drawn in a perspective manner in FIG. 9.

In the above embodiments, referring to FIG. 7 or 10, the semiconductor structure may further include a capacitor structure 109 located on one side of the second doped structure 102 distal to the gate structure 104. The bit line structure BL includes the third doped structure 103 and is located on one side of the gate structure 104 distal to the capacitor structure 109. In this way, it is conducive to preventing the capacitor structure 109 and the bit line structure BL from being directly opposite to each other, thereby helping to reduce the coupling effect of the capacitor structure 109 and the bit line structure BL on each other and thus improving the electrical performance of the semiconductor structure.

In some cases, at least a partial region of the second doped structure 102 is in contact with the gate dielectric layer 154 in the gate structure 104 corresponding to the second doped structure.

In summary, the second doped structure 102 and the third doped structure 103 may be regarded as being located on two opposite sides of the gate structure 104 along the first direction X. That is, taking a plane parallel to the first direction X as a reference plane, the second doped structure 102 and the third doped structure 103 are not directly opposite to each other; that is, the orthographic projections of the second doped structure 102 and the third doped structure 103 on the reference plane do not overlap, so as to increase the spacing between the second doped structure 102 and the third doped structure 103, thereby helping to reduce the coupling effect of the second doped structure 102 and the third doped structure 103 on each other. Further, the capacitor structure 109 is located on one side of the second doped structure 102 distal to the gate structure 104, and the bit line structure BL is located on one side of the gate structure 104 distal to the capacitor structure 109, which is conducive to preventing the capacitor structure 109 and the bit line structure BL from being directly opposite to each other, thereby helping to reduce the coupling effect of the capacitor structure 109 and the bit line structure BL on each other and thus improving the electrical performance of the semiconductor structure. In addition, two adjacent transistor structures along the second direction Y share one third doped structure 103, which is conducive to improving the integration density of the transistor structures in the semiconductor structure.

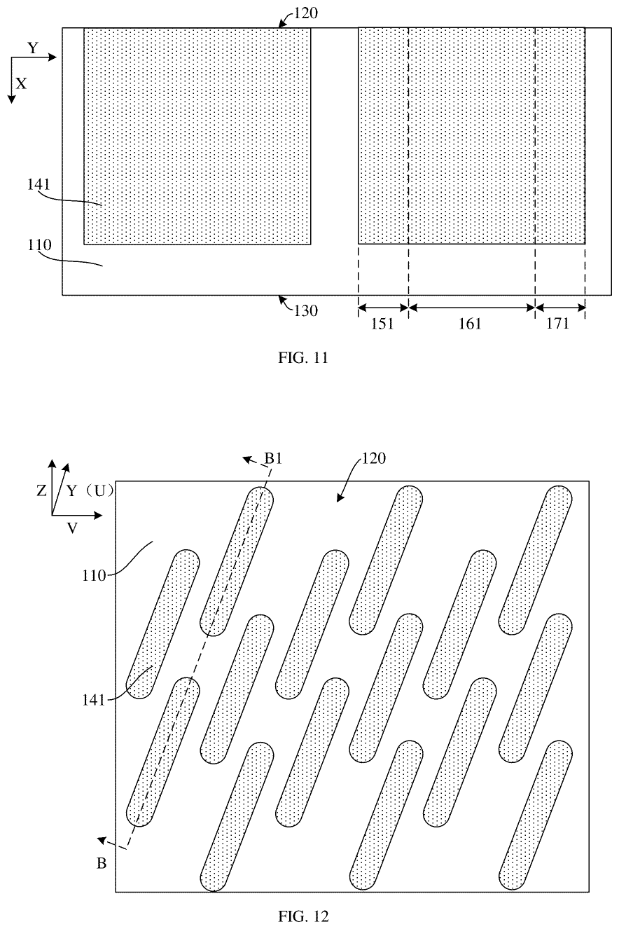

Another embodiment of the present disclosure further provides a method for manufacturing a semiconductor structure, which is used to form the semiconductor structure according to the foregoing embodiments. FIGS. 11 to 19 are schematic diagrams of cross-sectional structures corresponding to steps in a method for manufacturing a semiconductor structure according to another embodiment of the present disclosure. It should be noted that, for convenience of description and clear illustration of the steps in the method for manufacturing a semiconductor structure, FIGS. 11 to 19 in the embodiment are all schematic diagrams showing a partial structure of the semiconductor structure. In addition, the content that is the same as or corresponding to that in the foregoing embodiments will not be described herein again.

Referring to FIGS. 1 to 19, the method for manufacturing a semiconductor structure includes: providing an initial base substrate 110; performing doping treatment on different parts of the initial base substrate 110 by different doping processes to form a first doped structure 101, a second doped structure 102, and a third doped structure 103, where the first doped structure 101 is provided with a first portion 111, a second portion 121, and a third portion 131 that are sequentially arranged along a first direction X; the second doped structure 102 and the third doped structure 103 are spaced apart, the second doped structure 102 is in contact with the first portion 111, and the third doped structure 103 is in contact with the third portion 131; the first doped structure 101 is doped with one of N-type doping ions and P-type doping ions, and the second doped structure 102 and the third doped structure 103 are doped with the other of the N-type doping ions and the P-type doping ions; two adjacent first doped structures 101 along a second direction Y are in contact with the same third doped structure 103, and the second direction Y intersects with the first direction X; and forming a gate structure 104, where the gate structure 104 is provided with a first surface 114 and a second surface 124 that are opposite to each other along the second direction Y, at least the first surface 114 is in contact with the second portion 121, and the gate structure 104 is in contact with the third doped structure 103.

It should be noted that the sequence of steps of forming the second doped structure 102, the third doped structure 103, and the gate structure 104 may be adjusted, which will be described in detail below. In addition, for convenience of understanding, the method for manufacturing a semiconductor structure will be illustrated later by taking the formation of the semiconductor structure shown in FIG. 4 as an example. In practical applications, various semiconductor structures in the foregoing embodiments can be manufactured by the method for manufacturing a semiconductor structure according to another embodiment of the present disclosure.

In some embodiments, the initial base substrate 110 is provided with a front surface 120 and a back surface 130 that are opposite to each other along the first direction X. Referring to FIGS. 11 to 19, forming the second doped structure 102 and the third doped structure 103 may include the following steps.

Referring to FIGS. 11 and 12, first doping treatment is performed on a partial region of the initial base substrate 110 to form a plurality of initial first doped structures 141 spaced apart. The initial first doped structures 141 extend from the front surface 120 toward the inside of the initial base substrate 110. The initial first doped structures 141 also extend along a fourth direction U, and the initial first doped structures 141 are provided with a fourth portion 151, a fifth portion 161, and a sixth portion 171 that are sequentially arranged along the fourth direction U.

It should be noted that the first doped structure 101 is subsequently formed based on the initial first doped structure 141, and thus the initial first doped structure 141 is drawn by using the same filling method as the first doped structure 101 in FIGS. 11 to 19.

In some embodiments, performing the first doping treatment on the partial region of the initial base substrate 110 includes: doping the P-type doping ions into the partial region of the initial base substrate 110, so that the initial first doped structure 141 is doped with the P-type doping ions. In some other embodiments, performing the first doping treatment on the partial region of the initial base substrate 110 includes: doping the N-type doping ions into the partial region of the initial base substrate 110, so that the initial first doped structure 141 is doped with the N-type doping ions.

It can be understood that the initial first doped structure 141 may be regarded as an active region 106 before the second doped structure 102, the third doped structure 103, and the gate structure 104 are embedded. The orthographic projection of the initial first doped structure 141 on the top-view plane coincides with the orthographic projection of the active region 106 on the top-view plane, and the top-view plane is a plane formed by the third direction Z and the fifth direction V.

In some embodiments, referring to FIGS. 11 and 12, FIG. 11 is a schematic diagram of a partial cross-sectional structure of the semiconductor structure shown in FIG. 12 along a second cross-sectional direction BB1. The plurality of initial first doped structures 141 are spaced apart along both the third direction Z and the fifth direction V; moreover, two adjacent initial first doped structure groups spaced apart along the fifth direction V are offset in the third direction Z. Every two of the extension direction U of the initial first doped structure 141 itself, the third direction Z, and the fifth direction V intersect with each other; moreover, the extension direction U of the initial first doped structure 141 itself, the third direction Z, and the fifth direction V are located in one plane. It can be understood that, when a plurality of initial first doped structures 141 spaced apart along the third direction Z are regarded as one column, two adjacent columns are offset along the fifth direction V, and two columns spaced apart by one column are arranged in the same manner.

It should be noted that, in practical applications, the plurality of initial first doped structures may also be arranged in an array or in other arrangement manners along the third direction Z and the fifth direction V, and the arrangement manner of the plurality of initial first doped structures may be adjusted according to actual needs and is not limited herein. For convenience of description, the following detailed description is given by taking the case where the plurality of initial first doped structures 141 are arranged in the arrangement manner shown in FIG. 12 as an example.

Referring to FIGS. 11 to 14, FIG. 13 is a schematic diagram of a partial cross-sectional structure of the semiconductor structure shown in FIG. 14 along the second cross-sectional direction BB1. Second doping treatment is performed on both the fourth portion 151 and the sixth portion 171, so that along the first direction X, the fourth portion 151 of a partial thickness is converted into a second doped structure 102, and the sixth portion 171 of a partial thickness is converted into another second doped structure 102. The second doped structure 102 extends from the front surface 120 toward the inside of the initial base substrate 110.

It can be understood that the two second doped structures 102 are formed from two different regions of one initial first doped structure 141. That is, the two second doped structures 102 correspond to one initial first doped structure 141. The third doped structure 103 and the gate structure 104 may be subsequently formed in the fifth portion 161. In addition, the types of doping ions doped in the first doping treatment and the second doping treatment are different.

In some embodiments, on the basis that the initial first doped structure 141 is doped with the P-type doping ion, performing the second doping treatment on the fourth portion 151 and the sixth portion 171 includes: doping the fourth portion 151 and the sixth portion 171 with the N-type doping ions, so that the second doped structure 102 is doped with the N-type doping ions. In some other embodiments, on the basis that the initial first doped structure 141 is doped with the N-type doping ions, performing the second doping treatment on the fourth portion 151 and the sixth portion 171 includes: doping the fourth portion 151 and the sixth portion 171 with the P-type doping ions, so that the second doped structure 102 is doped with the P-type doping ions.

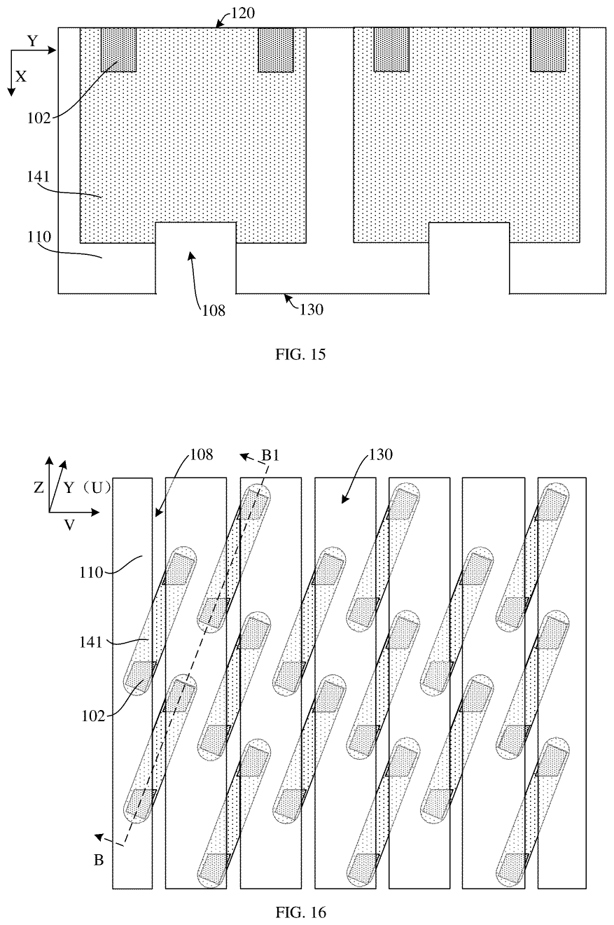

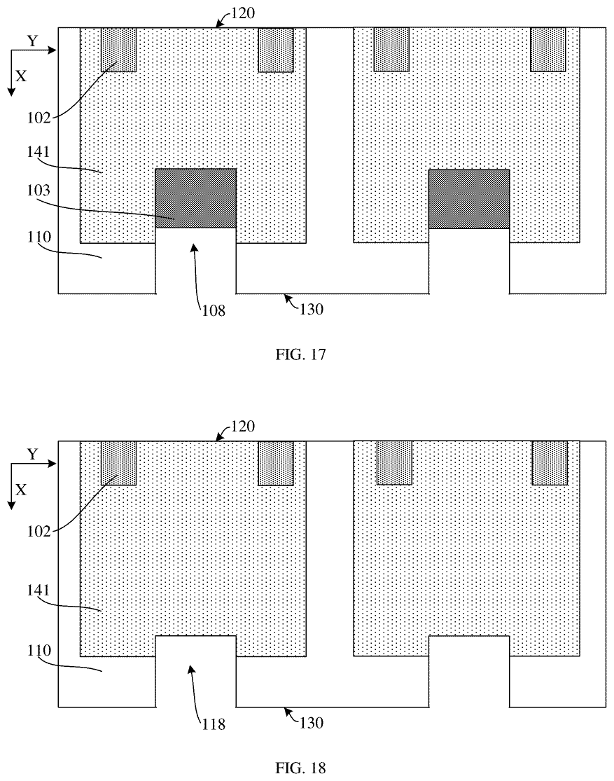

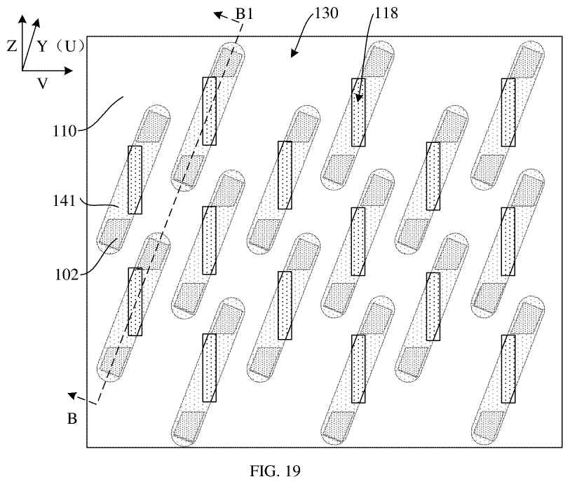

Referring to FIGS. 15 and 16 or referring to FIGS. 18 and 19, the initial base substrate 110 is patterned from the back surface 130 to expose at least a part of the fifth portion 161. Referring to FIG. 17 or referring to FIG. 10, third doping treatment is performed on the exposed fifth portion 161 to form the third doped structure 103.

The step of forming the third doped structure 103 is described in detail below in conjunction with two embodiments.

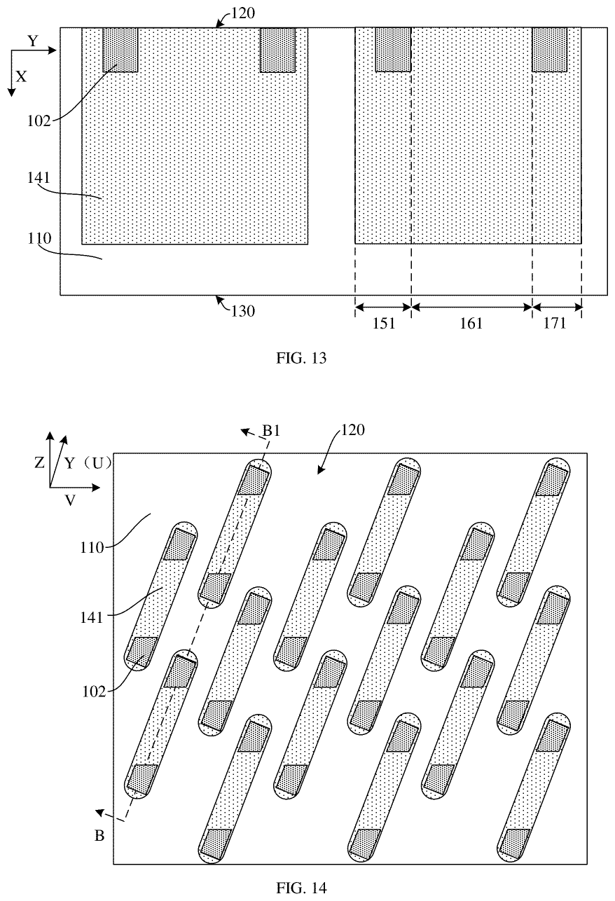

In some embodiments, referring to FIGS. 13 and 14, a plurality of fifth portions 161 are spaced apart along the third direction Z; every two of the first direction X, the second direction Y, and the third direction Z intersect with each other. The second direction Y is the extension direction U of the initial first doped structure 141.

In some embodiments, every two of the second direction Y, the third direction Z, and the fifth direction V intersect with each other and the three form a plane; the first direction X is perpendicular to the plane.

Patterning the initial base substrate 110 from the back surface 130 may include the following steps:

Referring to FIGS. 15 and 16, FIG. 15 is a schematic diagram of a partial cross-sectional structure of the semiconductor structure shown in FIG. 16 along the second cross-sectional direction BB1. The initial base substrate 110 is patterned from the back surface 130 to form a trench 108 extending along the third direction Z, and the trench 108 exposes the plurality of fifth portions 161 spaced apart along the third direction Z.

It should be noted that, in order to clearly illustrate the relative position relationship between the trench 108 and the initial base substrate 110 in the top view, the initial base substrate 110 is drawn in a perspective manner in FIG. 16.

Referring to FIGS. 15 to 17 and 8, the step of performing the third doping treatment on the exposed fifth portion 161 may include: performing the third doping treatment on the fifth portion 161 exposed by the trench 108 to form the third doped structure 103 extending along the third direction Z. It can be understood that one third doped structure 103 is in contact with the plurality of fifth portions 161 spaced apart along the third direction Z. In addition, the types of ions doped in the third doping treatment and the second doping treatment are the same.

In some embodiments, on the basis that the initial first doped structure 141 is doped with the P-type doping ions, performing the third doping treatment on the exposed fifth portion 161 includes: doping the exposed fifth portion 161 with the N-type doping ions, so that the third doped structure 103 is doped with the N-type doping ions. In some other embodiments, on the basis that the initial first doped structure 141 is doped with the N-type doping ions, performing the third doping treatment on the exposed fifth portion 161 includes: doping the exposed fifth portion 161 with the P-type doping ions, so that the third doped structure 103 is doped with the P-type doping ions.

Referring to FIGS. 17 and 7, the method for manufacturing a semiconductor structure may further include: forming a first electrical connection layer 117, where the first electrical connection layer 117 fills up the trench 108. It can be understood that the bit line structure BL may include a first electrical connection layer 117 and a third doped structure 103 in contact with the first electrical connection layer 117, and one bit line structure BL corresponds to one first electrical connection layer 117 and one third doped structure 103.

In some other embodiments, referring to FIGS. 13 and 14, a plurality of fifth portions 161 are spaced apart along the third direction Z; every two of the first direction X, the second direction Y, and the third direction Z intersect with each other. It should be noted that the content that is the same as or corresponding to that in the foregoing embodiments will not be described herein again.

Patterning the initial base substrate 110 from the back surface 130 may include the following steps:

Referring to FIGS. 18 and 19, FIG. 18 is a schematic diagram of a partial cross-sectional structure of the semiconductor structure shown in FIG. 19 along the second cross-sectional direction BB1. The initial base substrate 110 is patterned from the back surface 130 to form a plurality of through holes 118 spaced apart along the third direction Z, and each through hole 118 exposes one fifth portion 161.

It should be noted that, in order to clearly illustrate the relative position relationship between the through hole 118 and the initial base substrate 110 in the top view, the initial base substrate 110 is drawn in a perspective manner in FIG. 19.

Referring to FIGS. 18 to 19, 9, and 10, the step of performing the third doping treatment on the exposed fifth portion 161 may include: performing the third doping treatment on the fifth portion 161 exposed by the through hole 118 to form a plurality of third doped structures 103 spaced apart along the third direction Z. It can be understood that one third doped structure 103 is in contact with one fifth portion 161, that is, one third doped structure 103 corresponds to one fifth portion 161.

Referring to FIGS. 18 and 10, the method for manufacturing a semiconductor structure may further include: forming conductive pillars 127, where the conductive pillars 127 fill up the through holes 118, and the conductive pillars 127 are in a one-to-one correspondence with the through holes 118. In this way, the conductive pillars 127 are in a one-to-one correspondence with the third doped structures 103, that is, one conductive pillar 127 is in contact with one third doped structure 103.

Still referring to FIG. 10, a second electrical connection layer 137 extending along the third direction Z is formed, and the same second electrical connection layer 137 is in contact with a plurality of conductive pillars 127 spaced apart along the third direction Z.

It can be understood that the second electrical connection layer 137 and the plurality of conductive pillars 127 that are in contact with the second electrical connection layer 137 and spaced apart along the third direction Z jointly constitute a conductive layer 107; the bit line structure BL includes the conductive layer 107 and a plurality of third doped structures 103 in contact with the conductive layer 107.

In practical applications, after the initial base substrate is patterned from the back surface to form the plurality of through holes spaced apart along the third direction, and the third doping treatment is performed on the fifth portions exposed by the through holes to form the third doped structures, the base substrate on the back surface is patterned to form the trench extending along the third direction. One trench exposes the plurality of third doped structures spaced apart along the third direction, and a third electrical connection layer is formed in the trench. In this way, the bit line structure may include the third electrical connection layer and a plurality of third doped structures in contact with the third electrical connection layer. It may be understood that, after the third doped structure is formed by using the through hole, the through hole is expanded into the trench, and the third electrical connection layer is formed in the trench, so that one third electrical connection layer can supply power to a plurality of third doped structures.

In some embodiments, referring to FIGS. 5 and 10, the step of forming the gate structure 104 includes: patterning the fifth portion 161 (referring to FIG. 11) from the front surface 120 to form a second trench (not shown) extending along the fifth direction V. One fifth portion 161 corresponds to two adjacent second trenches along the third direction Z. The gate structure 104 and the isolation layer 105 are sequentially formed in the second trench. It should be noted that in the method for manufacturing a semiconductor structure according to another embodiment of the present disclosure, the specific process for forming the gate structure 104 and the isolation layer 105 is not limited and may be adjusted according to actual needs.

It should be noted that the step of forming the gate structure 104 may be performed before forming the second doped structure 102 and the third doped structure 103, or may be performed after forming the second doped structure 102 and the third doped structure 103. In addition, after the second doped structure 102, the third doped structure 103, and the gate structure 104 are formed in the initial first doped structure 141, the remaining initial first doped structure 141 serves as the first doped structure 101.

It can be understood that after the second doped structure 102, the third doped structure 103, and the gate structure 104 are formed, the remaining initial first doped structure 141 serves as the first doped structure 101, and the remaining initial base substrate 110 serves as the base substrate 100.

In some embodiments, still referring to FIG. 10, after forming the second doped structure 102, the method for manufacturing a semiconductor structure may further include: forming, on the front surface 120, a capacitor structure 109 in contact with the second doped structure 102. One second doped structure 102 corresponds to one capacitor structure 109.

In summary, in the formed semiconductor structure, the second doped structure 102 and the third doped structure 103 may be regarded as being located on two opposite sides of the gate structure 104 along the first direction X. That is, taking a plane parallel to the first direction X as a reference plane, the second doped structure 102 and the third doped structure 103 are not directly opposite to each other; that is, the orthographic projections of the second doped structure 102 and the third doped structure 103 on the reference plane do not overlap, so as to increase the spacing between the second doped structure 102 and the third doped structure 103, thereby helping to reduce the coupling effect of the second doped structure 102 and the third doped structure 103 on each other. Further, the capacitor structure 109 is located on one side of the second doped structure 102 distal to the gate structure 104, and the bit line structure BL is located on one side of the gate structure 104 distal to the capacitor structure 109, which is conducive to preventing the capacitor structure 109 and the bit line structure BL from being directly opposite to each other, thereby helping to reduce the coupling effect of the capacitor structure 109 and the bit line structure BL on each other and thus improving the electrical performance of the semiconductor structure. In addition, two adjacent transistor structures along the second direction Y share one third doped structure 103, which is conducive to improving the integration density of the transistor structures in the semiconductor structure.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

1. A semiconductor structure, comprising:
a first doped structure, provided with a first portion, a second portion, and a third portion that are sequentially arranged along a first direction;
a second doped structure and a third doped structure that are spaced apart, wherein the second doped structure is in contact with the first portion, and the third doped structure is in contact with the third portion,
wherein the first doped structure is doped with one of N-type doping ions and P-type doping ions, the second doped structure and the third doped structure are doped with the other of the N-type doping ions and the P-type doping ions, two adjacent first doped structures along a second direction are in contact with a same third doped structure, and the second direction intersects with the first direction; and
a gate structure, provided with a first surface and a second surface that are opposite to each other along the second direction, at least the first surface or the second surface being in contact with the second portion.

2. The semiconductor structure according to claim 1, wherein in the gate structure, the first surface or the second surface is in contact with the second portion.

3. The semiconductor structure according to claim 2, wherein the gate structure is provided with a third surface and a fourth surface that are opposite to each other along the first direction, at least a part of the third surface is also in contact with the second portion, and at least a part of the fourth surface is also in contact with the second portion.

4. The semiconductor structure according to claim 2, wherein the gate structure is provided with a third surface and a fourth surface that are opposite to each other along the first direction, and the second surface and the fourth surface are also in contact with the second portion.

5. The semiconductor structure according to claim 4, further comprising: an isolation layer, in contact with the third surface, wherein the isolation layer and the gate structure are both embedded into the first doped structure.

6. The semiconductor structure according to claim 4, further comprising: an active region, wherein the active region comprises two adjacent first doped structures along the second direction, and two gate structures in contact with the two first doped structures are spaced apart from each other and both located in the active region.

7. The semiconductor structure according to claim 1, wherein at least a part of the second doped structure is embedded into the first portion, or at least a part of the third doped structure is embedded into the third portion.

8. The semiconductor structure according to claim 1, wherein a plurality of first doped structures and a plurality of second doped structures are spaced apart along a third direction, and the plurality of first doped structures and the plurality of second doped structures that are spaced apart along the third direction are all in a one-to-one correspondence with the gate structures; the third doped structure extends along the third direction, one third doped structure is in contact with the plurality of first doped structures spaced apart along the third direction, and every two of the first direction, the second direction, and the third direction intersect with each other.

9. The semiconductor structure according to claim 1, wherein a plurality of first doped structures, a plurality of second doped structures, and a plurality of third doped structures are spaced apart along a third direction, and the plurality of first doped structures, the plurality of second doped structures, and the plurality of third doped structures that are spaced apart along the third direction are all in a one-to-one correspondence with the gate structures;
the semiconductor structure further comprises a conductive layer extending along the third direction, and a same conductive layer is in contact with the plurality of third doped structures spaced apart along the third direction.

10. The semiconductor structure according to claim 1, further comprising: a first electrical connection layer, wherein the first electrical connection layer is located on one side of the third doped structure distal to the gate structure, and the first electrical connection layer extends along a third direction.

11. The semiconductor structure according to claim 1, wherein the gate structure is in contact with the third doped structure.

12. The semiconductor structure according to claim 11, wherein the gate structure comprises: a gate dielectric layer and a gate, and the gate dielectric layer is located between the gate and the second portion.

13. The semiconductor structure according to claim 12, wherein the gate and the third doped structure are spaced apart by at least the gate dielectric layer.

14. The semiconductor structure according to claim 12, wherein at least a partial region of the second doped structure is in contact with the gate dielectric layer.

15. The semiconductor structure according to claim 1, further comprising: a base substrate, wherein the first doped structure, the second doped structure, the third doped structure, and the gate structure are all located in the base substrate.

16. A method for manufacturing a semiconductor structure, comprising:
providing an initial base substrate;
performing doping treatment on different parts of the initial base substrate by different doping processes to form a first doped structure, a second doped structure, and a third doped structure,
wherein the first doped structure is provided with a first portion, a second portion, and a third portion that are sequentially arranged along a first direction; the second doped structure and the third doped structure are spaced apart, the second doped structure is in contact with the first portion, and the third doped structure is in contact with the third portion; the first doped structure is doped with one of N-type doping ions and P-type doping ions, and the second doped structure and the third doped structure are doped with the other of the N-type doping ions and the P-type doping ions; two adjacent first doped structures along a second direction are in contact with a same third doped structure, and the second direction intersects with the first direction; and
forming a gate structure, wherein the gate structure is provided with a first surface and a second surface that are opposite to each other along the second direction, at least the first surface is in contact with the second portion, and the gate structure is in contact with the third doped structure.

17. The method for manufacturing a semiconductor structure according to claim 16, wherein the initial base substrate is provided with a front surface and a back surface that are opposite to each other along the first direction; the step of forming the second doped structure and the third doped structure comprises:
performing first doping treatment on a partial region of the initial base substrate to form a plurality of initial first doped structures spaced apart, wherein each of the plurality of initial first doped structures extends from the front surface toward inside of the initial base substrate, the initial first doped structure also extends along a fourth direction, and the initial first doped structure is provided with a fourth portion, a fifth portion, and a sixth portion that are sequentially arranged along the fourth direction;
performing second doping treatment on both the fourth portion and the sixth portion, so that along the first direction, the fourth portion of a partial thickness is converted into one second doped structure, and the sixth portion of a partial thickness is converted into another second doped structure, each of the second doped structures extending from the front surface toward the inside of the initial base substrate;
patterning the initial base substrate from the back surface to expose at least a part of the fifth portion; and
performing third doping treatment on the exposed fifth portion to form the third doped structure.

18. The method for manufacturing a semiconductor structure according to claim 17, wherein a plurality of fifth portions are spaced apart along a third direction, and every two of the first direction, the second direction, and the third direction intersect with each other;
patterning the initial base substrate from the back surface comprises:
patterning the initial base substrate from the back surface to form a trench extending along the third direction, wherein the trench exposes the plurality of fifth portions spaced apart along the third direction;
performing the third doping treatment on the exposed fifth portion comprises:
performing the third doping treatment on the fifth portion exposed by the trench to form the third doped structure extending along the third direction;
the method for manufacturing a semiconductor structure further comprises: forming a first electrical connection layer, wherein the first electrical connection layer fills up the trench.

19. The method for manufacturing a semiconductor structure according to claim 17, wherein a plurality of fifth portions are spaced apart along a third direction, and every two of the first direction, the second direction, and the third direction intersect with each other;
patterning the initial base substrate from the back surface comprises:
patterning the initial base substrate from the back surface to form a plurality of through holes spaced apart along the third direction, wherein each of the plurality of through holes exposes one of the plurality of fifth portions;
performing the third doping treatment on the exposed fifth portion comprises:
performing the third doping treatment on the fifth portion exposed by the through hole to form a plurality of third doped structures spaced apart along the third direction;
the method for manufacturing a semiconductor structure further comprises: forming conductive pillars, wherein the conductive pillars fill up the plurality of through holes, and the conductive pillars are in a one-to-one correspondence with the plurality of through holes; and
forming a second electrical connection layer extending along the third direction, wherein a same second electrical connection layer is in contact with a plurality of conductive pillars spaced apart along the third direction.

20. The method for manufacturing a semiconductor structure according to claim 17, wherein after forming the second doped structure, the method for manufacturing a semiconductor structure further comprises: forming, on the front surface, a capacitor structure in contact with the second doped structure, and one second doped structure corresponds to one capacitor structure.
